(19) United States
(12) Patent Application Publication
(10) Pub. No.: US 2008/0054257 A1
(43) Pub. Date: Mar. 6, 2008

(54) THIN-FILM TRANSISTOR AND FABRICATION METHOD THEREOF

(75) Inventors: Hsuan-Ming Tsai, Tainan Hsien (TW); Yuh-Zheng Lee, Hsinchu City (TW); Chao-Kai Cheng, Miaoli County (TW); Jhih-Ping Lu, Yi-Lan City (TW); Kuo-Tong Lin, Taipei County (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/780,450

(22) Filed: Jul. 19, 2007

(30) Foreign Application Priority Data
Sep. 5, 2006 (TW) TW95132720

(51) Int. Cl. H01L 51/00; H01L 51/40

(52) U.S. Cl. 257/40; 438/99; 257/E51.005

(57) ABSTRACT

A thin-film transistor and fabrication method thereof are provided. A controlled micro-line is formed by inkjet printing in combination with the coffee ring effect. At least two organic thin-film transistors are formed on two ring ridges of the coffee rings. For example, N-type and P-type soluble semiconductor materials may be formed on two adjacent ring ridges to form a complementary metal-oxide semiconductor (CMOS) device. Thus, the invention can simplify the process for fabricating thin-film transistors and increase their applications.

### FIELD OF THE INVENTION

The invention relates to a thin-film transistor, and more particularly to a thin-film transistor formed by inkjet printing in combination with the coffee ring effect.

2. Description of the Related Art

Organic polymer material is stable and soluble, thus, a solution of polymer material be utilized in fabricating products by dispensing. The process of dispensing method is simple and the cost thereof is reduced largely. The dispensing method is simple and the cost is relatively low.

Micrometer scale drops can be formed on a substrate by inkjet printing of pico volume droplets, thus, a micrometer sized electronic device can be fabricated. In general, the diameter of the drop on the substrate is from several tens to several hundreds of micrometers, and is thus too large for high resolution electronic devices.

A mechanism for forming coffee rings is shown in FIG. 1A to FIG. 1C. The mechanism can be referenced in Nature, Vol. 389, 1997, Robert D. Deegan, Olgica Bakajin et al., “Capillary Flow as the Cause of Ring Stains from Dried Liquid Drops”. In this article, the natural phenomenon of a solution containing a solid solute drying into a coffee ring is illustrated. An ink drop 12 is formed on a substrate 10, a perimeter of the drop is rapidly dried to form a contact line 14. Here, the characteristic pattern of the coffee ring forms a capillary flow in which pinning of the contact line of the drying drop ensures that liquid evaporating from the edge is replenished by liquid from the interior. The phenomenon is due to a geometrical constraint: the free surface, constrained by a pinned contact line, squeezes the fluid outward to compensate for evaporative losses. The coffee ring remains as long as (1) the solvent meets the surface of the substrate at a non-zero contact angle, (2) the contact line 14 is formed on the substrate 10 from the drop 12 (i.e., the drop 12 containing a solute 16), (3) the solvent evaporates. Additionally, the mechanisms are typically responsible for solute transport, thus, surface tension gradients, solute diffusion, electrostatic and gravitational effects are negligible in coffee ring formation.

Thin-film transistors (TFT) used in inorganic semiconductors among others, have been reduced to the 60 nm scale. Although 60 nm scale technology is applicable to general displays and electronic devices, organic material and soluble semiconductor materials show better potential for mass production of electronic devices due to the simpler process and lower cost thereof. Organic material is also more suitable than inorganic material for fabrication on flexible substrates. The process used for organic material is better than photolithography and high temperature processes utilized for inorganic material in cost and for electronic products currently on the market. Conventional film forming technologies comprise vacuum deposition, spin-coating, or screen printing. These technologies, however, are unable to extend the length of a gate (i.e. TFT channel resolution) to several micrometers and less. A micro-contact printing and a nanoimprinting are able to form a micro-line, however, in fabrication on a large sized substrate, these technologies have difficulties in repeated alignment and mass production. Reducing the length and increases the width of a gate forms a high-current TFT, thus, shorter, wider gates are desirable.

Direct writing technology is widely used for circuit element fabrication. For example, Xennia and Carclo have used inkjet printing to form a conductive metal wire with a width of about 50 μm on a plastic or paper substrate. An organic TFT can be fabricated by inkjet printing, but the gate line of TFT is still fabricated by photolithography to form a width of 5 μm. In “Using convective flow splitting for the direct printing of fine copper lines” Appl. Phys. Vol. 77, No. 13, p. 2063, Tanja et al. of Princeton College utilized the phenomenon of convective flow splitting to form a Cu conductive wire. Dispensing, and then vaporizing solvent reduced the width of the formed 500 μm Cu conductive wire to form a wire with a width of 100 μm. The Cu wire can be fabricated by inkjet printing to achieve an initial width of 80 μm, and then, by vaporizing solvent, reduced to a width of 10 μm. Although the width of the wire is reduced by the coffee ring effect, there is still a solute in the central part of the coffee ring. Because there are no isolated lines formed by the described technology, it cannot be used for fabricating an electronic device.

U.S. Pat. No. 6,284,562 discloses a complementary metal-oxide semiconductor (CMOS) device of organic material. In this CMOS device, tetracene or pentacene with N type and P type characters together can be used for CMOS device fabrication. The disadvantage of this fabrication method is that the film forming technology thereof is a higher cost vacuum deposition.

U.S. Pat. No. 6,838,361 discloses a TFT fabrication method. In this method, only one ridge of the coffee ring is used for electronic device fabrication. However, the coffee ring formed by inkjet printing has two ridges, if only one ridge is used, the gap between the device will be widened such that high density and high resolution fabrication is hindered. Additionally, in this method, after source/drain electrodes are formed, a lift-off process removes the coffee ring. The disadvantages of this method include an additional cost for a lift-off process. At the same time, lift-off processes damage the surfaces of the source/drain electrodes.

The invention employs an inkjet printing and an etching process disclosed in Taiwan Patent No. I224361 to form and reduce the width of an isolated line. The character of the fine line is further utilized to form a TFT.

### BRIEF SUMMARY OF THE INVENTION

The invention utilizes the ridges of a ring profile to form a thin-film transistor (TFT) and the ring profile is formed by inkjet printing in combination with a coffee ring effect to achieve a simpler process and to widen an application range thereof.

The invention provides a TFT, wherein different materials may be disposed on the same plane as the TFT. N type and P type materials with similar character are chosen in combination with different dielectric materials to form an optimum TFT device. Additionally, the central part of a coffee ring film can be removed by etching to form an isolated line and reduce the width of the line by a controlled etching rate. The conventional lift-off process is not necessary for the TFT, and the remaining coffee ring can be removed by dissolving with a soluble semiconductor solution, or the remaining coffee ring can be retained to form the TFT.

An exemplary TFT of the invention comprises a separating layer disposed over a substrate, wherein the separating layer includes a first ridge and a second ridge of a ring profile. A source/drain layer is disposed on opposite sides of the first ridge and opposite sides of the second ridge. A first semiconductor layer is disposed on the first ridge and portions of the source/drain layer adjacent to the first ridge. A second semiconductor layer is disposed on the second ridge and portions of the source/drain layer adjacent to the second ridge. A first gate dielectric layer and a first gate layer are disposed over the substrate, thus a metal-oxide semiconductor (MOS) device is fabricated.

The invention further provides a method for fabricating a thin-film transistor, comprising inkjet printing a separating layer over a substrate to form a coffee ring. A central part of the coffee ring is then removed by etching leaving a first ridge and a second ridge. A source/drain layer is formed on opposite sides of the first ridge and opposite sides of the second ridge by inkjet printing. A first semiconductor layer is disposed on the first ridge and portions of the source/drain layer adjacent to the first ridge by inkjet printing or coating. A second semiconductor layer is disposed on the second ridge and portions of the source/drain layer adjacent to the second ridge by inkjet printing or coating. A first gate dielectric layer and a first gate layer are then formed over the substrate by inkjet printing or coating to complete a metal-oxide semiconductor (MOS) device.

The above TFT device design and the process concepts of forming a semiconductor channel by inkjet printing a coffee ring are not limited to the described structure and process. A TFT device with a bottom gate layer or with an upper and a bottom gate layers is also suited to the above TFT device design and the process concepts.

A detailed description is given in the following embodiments with reference to the accompanying drawings.

### BRIEF DESCRIPTION OF THE DRAWINGS

The invention can be more fully understood by reading the subsequent detailed description and examples with reference to the accompanying drawings, wherein:

FIGS. 1A-1C show schematic cross sections of a mechanism for forming coffee rings;

FIG. 2A-2F show schematic cross sections of processes for forming an upper gate TFT of a first embodiment of the invention;

FIG. 3A shows an equivalent circuitry of a separate dual devices TFT of a first embodiment of the invention;

FIG. 3B shows an equivalent circuitry of combining the separate dual devices TFT of FIG. 3A into one device TFT;

FIG. 4 shows a device electric measurement curve of an upper gate TFT of a first embodiment of the invention;

FIG. 5 shows a schematic cross section of a upper gate CMOS TFT of a second embodiment of the invention;

FIG. 6 shows a schematic cross section of a bottom gate TFT of a third embodiment of the invention;

FIG. 7 shows a schematic cross section of a bottom gate CMOS TFT of a fourth embodiment of the invention;

FIG. 8 shows a schematic cross section of a dual-gate TFT of a fifth embodiment of the invention;

FIG. 9 shows a schematic cross section of a dual-gate CMOS TFT of a sixth embodiment of the invention.

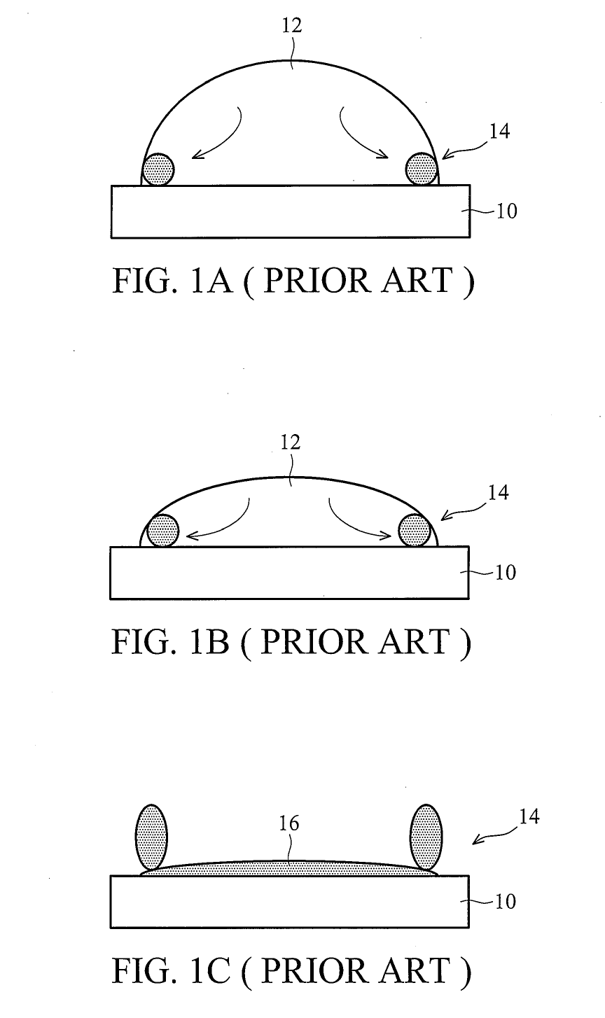

### DETAILED DESCRIPTION OF THE INVENTION

The following description is of the best-contemplated mode of carrying out the invention. The description is provided for illustrating the general principles of the invention and is not meant to be limiting. The scope of the invention is best determined by reference to the appended claims.

The invention utilizes an inkjet printing technology and the natural phenomenon of a solution drop drying into a coffee ring to make a micro-line structure of the coffee ring ridge. A micro-line structure having two ridges can be utilized in fabricating dual TFT and CMOS devices. Additionally, the dual TFT can be further connected into one device to reduce area, simplify process, and enhance yield rate.

The conventional electric device only uses one ridge of the coffee ring such that the gap between the devices is increased and not suited for high density and high resolution applications. The ridge of the coffee ring can be treated to adjust the contact angle with a solution such that a self-alignment effect can be achieved. The invention uses two ridges of the coffee ring in combination with electrode design and inkjet printing to form the three types of devices as described in the following.

1. Two devices with one end connected, which can be used for simplifying circuit structure and reducing area of a device with more than two TFTs.

2. A CMOS device having N type and P type soluble semiconductor or semiconductor precursor material disposed on two adjacent channels by inkjet printing respectively.

3. A Dual-gate TFT increasing the effective channel width of a TFT and enhancing device current.

Thus, the device can be fabricated into an amplifier circuit, a feedback circuit, a CMOS or a dual-gate TFT.

### FIRST EMBODIMENT

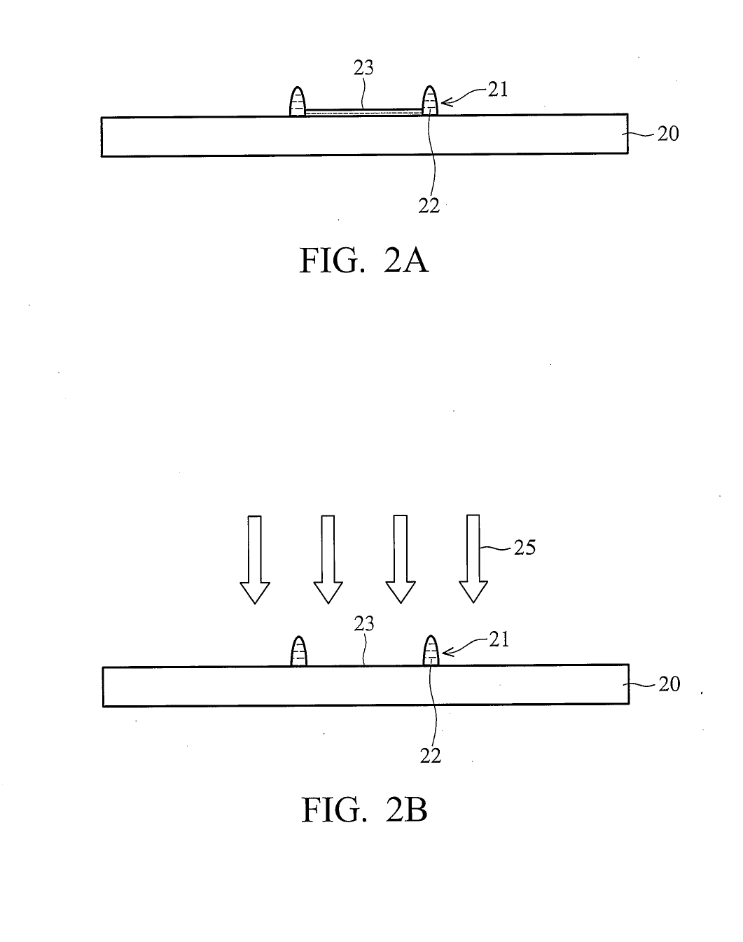

FIGS. 2A-2F show cross sections of fabrication steps of a first embodiment of the invention. Referring to FIG. 2A, a substrate 20, such as glass, silicon, plastic substrate or other flexible substrate, is first provided. The selected substrate is then cleaned and treated by a surface treatment step such as plasma treatment. A polymer solution is inkjet printed by a sprinkle-nozzle on the substrate 20 into a dot or a line shape, and then dried into a coffee ring film 21. The polymer may be, but is not limited to, poly(3-alkylthiophene) (P3AT), poly(9,9-dioctylfluorene-co-bithiophene) (F8T2), polymethyl methacrylate (PMMA), poly(4-vinylphenol) (PVP), polyvinyl alcohol (PVA), polyacrylonitrile (PAN), polyimide (PI), or polyoxymethylene (POM). The polymer is dissolved in a solvent into a solution for inkjet printing. The solvent includes a watery liquid or an oily liquid.

Referring to FIG. 2B, a central part 23 of the coffee ring film 21 is removed by an etching method, and two coffee ring ridges 22 are left as a separating layer. The width of the ridge is about 1˜50 μm, and the height of the ridge is about 100˜5000 Å. If the polymer solution is inkjet printed on the substrate 20 into the shape of a line, two parallel micrometer scale lines are formed on the substrate. As shown in FIG. 2B, the coffee ring ridges 22 are treated with plasma 25 to make the coffee ring ridges 22 hydrophobic and to increase affinity of coffee ring ridges 22 to a semiconductor solution. The utilized plasma gas may be O₂, N₂, CF₄, SF₆ or combinations thereof. The etching method may be a surface micro-etching method, but is not limited to plasma treatment, which can be practiced by dipping, spraying, dispensing, printing or combinations thereof. The spraying, dispensing or printing is practiced by sprinkling a solvent on the substrate to etch the thin central part of the coffee ring.

FIG. 2C shows a solution of conductive material inkjet printed on the coffee ring ridge 22 into two separate areas due to the hydrophobic coffee ring ridge. The two separate areas are formed into films on the two sides of the ridge as a source layer 24 and a drain layer 26. The solution of conductive material may be an inkjet printed electrode material, or an ink solution of conductive polymer, wherein poly-3,4-ethylenedioxythiophene (PEDOT) or nanometal solution such as nanosilver paste is preferable.

Referring to FIG. 2D, a semiconductor layer 28 is inkjet printed or coated on the coffee ring ridge 22, and portions of the source layer 24 and the drain layer 26 adjacent to the coffee ring ridge 22. The semiconductor layer is formed from a solution of semiconductor material which can be inkjet printed. The semiconductor material may be, but is not limited to the following materials or combinations thereof: a nanoderivative of an inorganic semiconductor such as ZnO; a derivative of a carbon cluster such as [6,6]-phenyl C61-butyric acid methyl ester (PCBM), pentacene precursor, P3AT, or F8T2; other semiconductor materials with negative charge which contain the cyanogen group or the heterocycle group, for example, dicyano perylene-3,4,9,10-bis(dicarboximides) (PDI-CN₂) or derivatives thereof. The semiconductor layer can also be formed by vacuum deposition or vapor deposition, and the materials thereof may be an organic semiconductor material such as pentacene or PCBM.

Referring to FIG. 2E, an upper gate dielectric layer 30 is inkjet printed, coated or vacuum deposited on the semiconductor layer 28, the source layer 24 and the drain layer 26. The upper gate dielectric layer can be formed of an organic or inorganic insulating material. The organic insulating material is, for example, PMMA, PVP, PVA, PAN, PI or POM. The inorganic insulating material is, for example, SiO₂, Ta₂O₅, Al₂O₃, or Si₃N₄. The material of the upper gate dielectric layer also may be combinations of the stated organic polymer and the inorganic nanoderivative.

Referring to FIG. 2F, an upper gate layer 32 is finally inkjet printed or coated on the upper gate dielectric layer 30 and aligned with the separating layer 22 to form a TFT. The upper gate layer can be formed from a metal or a solution of conductive material. The conductive material is, for example, PEDOT or nanosilver paste. The metal is, for example, Ag, Al, Au, alloys thereof or combinations thereof. The structure of the metal may comprise one, or more than one layer.

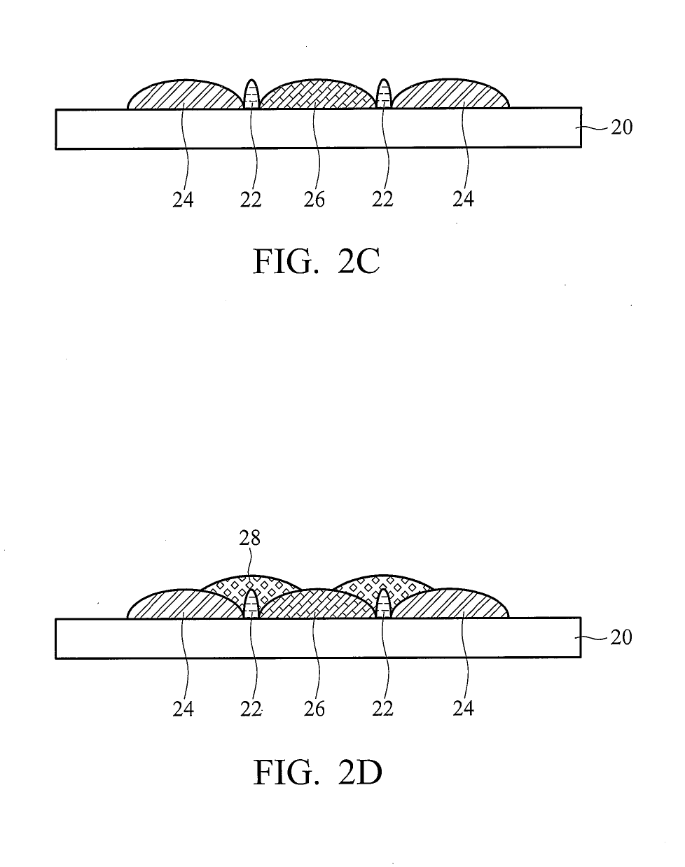

An equivalent circuitry of the TFT of FIG. 2F is as shown in FIG. 3A, wherein the TFT is a separated a dual device type TFT. All applications based on this kind of circuitry can utilize the TFT structure of the invention. The conductive films inkjet printed on the exterior sides of the two ridges are connected into a common electrode. An equivalent circuitry connecting method is shown as FIG. 3B. The dual devices of the TFT are combined into one device such that two channels are connected into one wider channel to enhance the current of the device.

The invention can complete a high current, micro-length gate, interconnecting dual devices, and dual current devices by inkjet printing, vacuum or low pressure film forming methods or combinations thereof, without requiring photolithography and etching processes.

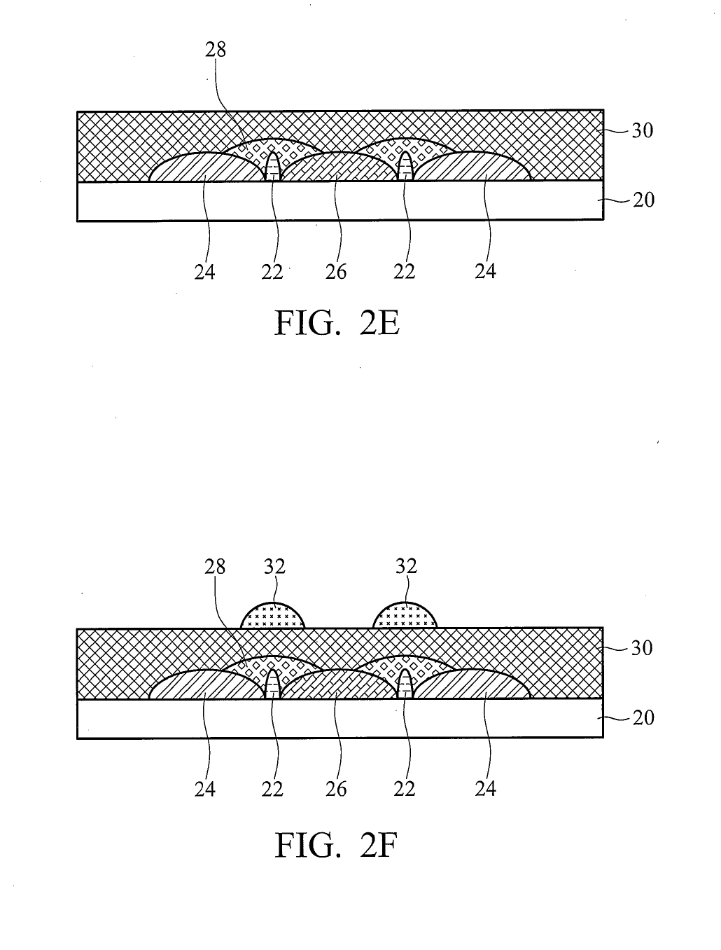

An electric measurement curve of the device with a structure of one ridge is shown as FIG. 4, wherein the separating layer 22 is comprised of PMMA, the source layer 24 and the drain layer 26 are comprised of PEDOT, the semiconductor layer 28 is made of P3AT, the upper gate dielectric layer 30 is comprised of PVP, and the upper gate layer is comprised of PEDOT. The mobility of the organic TFT formed from the above materials is above 8.81*10⁻² cm²/V−s and the gate critical voltage (Vt) is about 3.89V. As shown in FIG. 4, the drain current is labeled as Id, the gate voltage is labeled as Vg, and the drain voltage is labeled as Vd.

### SECOND EMBODIMENT

In the second embodiment of the invention, the different semiconductor materials are inkjet printed on the two ridges, one is N type semiconductor, and the other is P type semiconductor, thus completing a CMOS TFT structure.

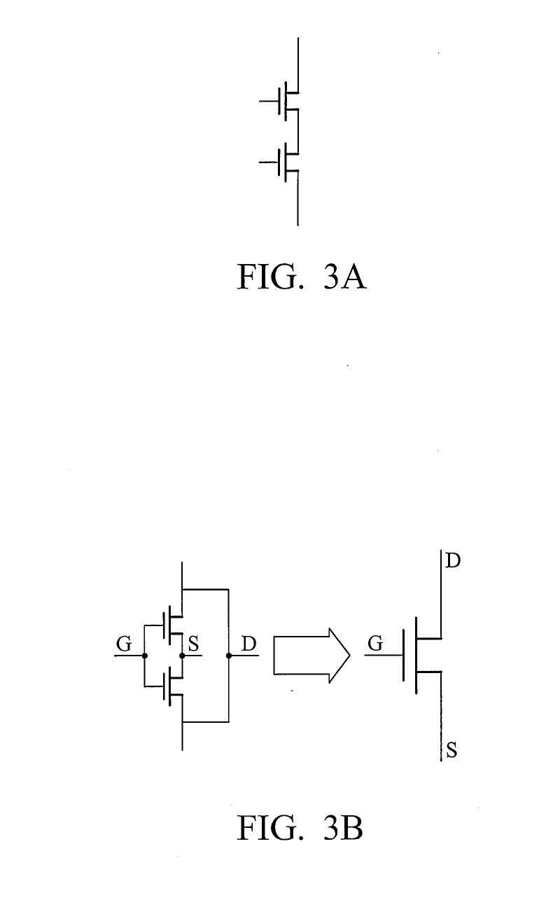

As shown in FIG. 5, a substrate 20 is first provided, and then two ridges 22 of the coffee ring are formed on the substrate 20 as a separating layer. A source layer 24 and a drain layer 26 are disposed on opposite sides of the ridge 22. A P type semiconductor layer 27 is disposed on one ridge 22 and portions of the source/drain layer. An N type semiconductor layer 29 is disposed on the other ridge 22 and portions of the source/drain layer. A gate dielectric layer 30 is disposed on the P type semiconductor layer 27, the N type semiconductor layer 29, the source layer 24 and the drain layer 26. A gate layer 32 is disposed on the gate dielectric layer 30, corresponding to the ridges 22. In the second embodiment, with the exception of the P type semiconductor layer 27 and the N type semiconductor layer 29, the material and fabrication method of the other layers are the same as the first embodiment. In the second embodiment, the material of the P type semiconductor layer 27 is preferably pentacene, P3AT or a derivative of PF polymer. The material of the N type semiconductor layer 29 is preferably ZnO, PCBM, or other semiconductor material with negative charge, which contain the cyanogen group or the heterocycle group, for example, dicyano perylene-3,4,9,10-bis(dicarboximides) (PDI-CN₂). The P type and N type semiconductor layers are both formed by inkjet printing.

### THIRD EMBODIMENT

According to the structure of the first embodiment, wherein the substrate can be replaced by a substrate having a conductive layer and an inorganic gate dielectric layer, and the upper gate layer and the upper gate dielectric layer can be removed to form a bottom gate device.

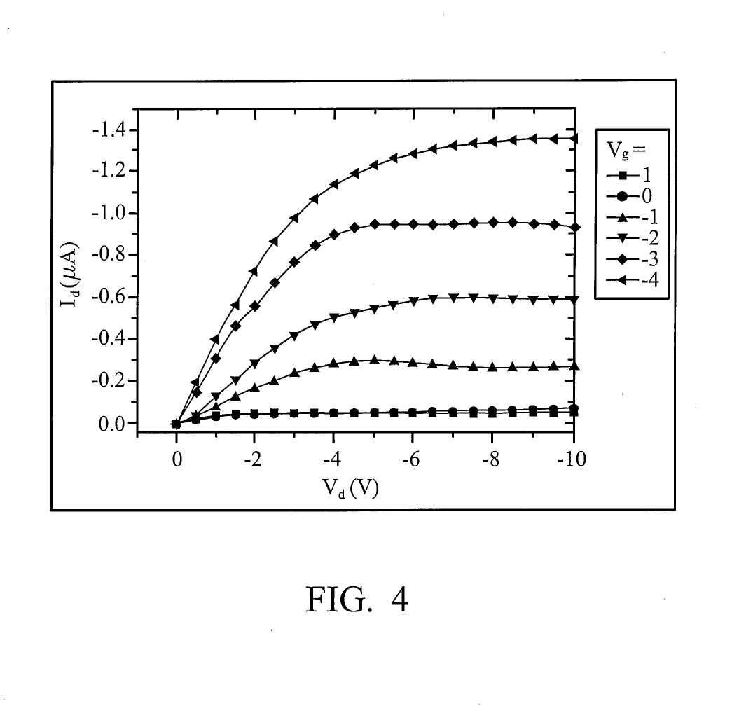

The third embodiment of the invention is as shown in FIG. 6. A substrate 40 is first provided. A bottom gate layer 42 is disposed on the substrate 40, and the patterning process thereof is not required. The material of the bottom gate layer 42 may be a heavily doped N type or P type semiconductor such as a heavily doped Si, Ge, or GaAs; an organic conductive film such as PEDOT; or a metal or an inorganic conductive film such as ITO, IZO, Ag, Au, Al, or Cr. A bottom gate dielectric layer 44 is disposed above the bottom gate layer 42, and underlying a separating layer 46 and a source/drain layer 48/50. The material of the bottom gate dielectric layer 44 may be an inorganic insulating material, an organic insulating material or combinations thereof, the material is preferably an inorganic insulating material such as SiO₂, Ta₂O₅, Al₂O₃, or Si₃N₄.

After cleaning and surface treating the bottom gate dielectric layer 44, the other layers include the ridges 46, the source layers 48, the drain layer 50, and the semiconductor layers 52 are formed on the bottom gate dielectric layer 44 to complete a bottom gate TFT device according to the material and fabrication method of the first embodiment.

### FOURTH EMBODIMENT

The difference between the fourth and the third embodiments is that the material of the semiconductor layers inkjet printed on the two ridges of the fourth embodiment are different. The difference between the fourth and the second embodiments is that, in the fourth embodiment, a bottom gate structure is used in the fourth embodiment. The fourth embodiment use N type semiconductor inkjet printed on one ridge, and P type semiconductor inkjet printed on the other ridge to form a CMOS TFT.

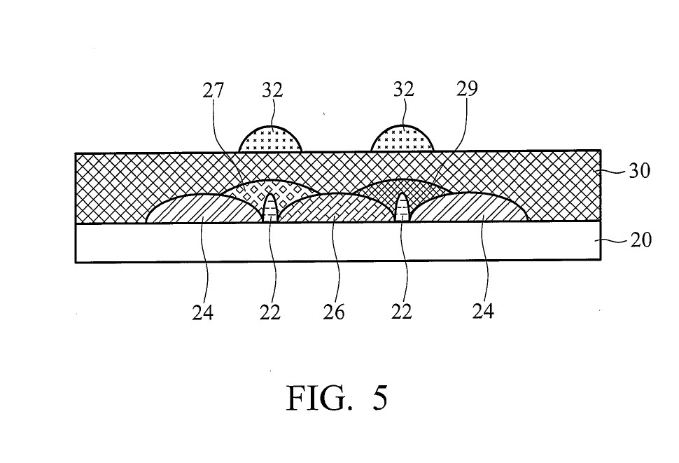

As shown in FIG. 7, a substrate 40 is first provided. A bottom gate layer 42 is then disposed on the substrate 40. A bottom gate dielectric layer 44 is disposed above the bottom gate layer 42, and underlying a separating layer 46 and a source/drain layer 48/50. The P type semiconductor layer 51 is disposed on one ridge 46 and portions of the source/drain layer 48/50. The N type semiconductor layer 53 is disposed on the other ridge 46 and portions of the source/drain layer 48/50. The positions of the P type and N type semiconductor layers can be exchanged. The material of the P type semiconductor layer 51 is the same as the first embodiment. The material of the N type semiconductor layer 53 is the same as the second embodiment. The material and fabrication method of the bottom gate layer 42 and the bottom gate dielectric layer 44 are the same as the third embodiment. The material and fabrication method of the other layers are the same as the first embodiment.

### FIFTH EMBODIMENT

Combining the structures of the first and the third embodiments and using the upper gate and the bottom gate structures can form a TFT device with double gate structure. Thus, the operative current and on/off ratio of the TFT device, and the performance of the device can be enhanced.

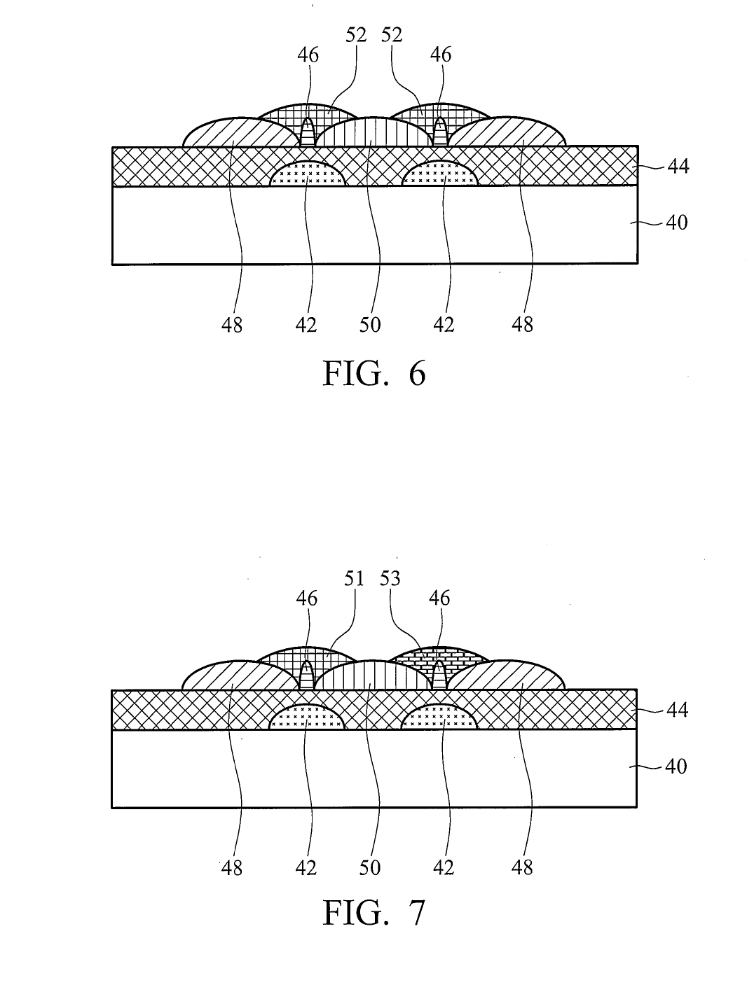

The fifth embodiment of the invention is as shown as FIG. 8. A substrate 40 is first provided. A bottom gate layer 62 is disposed on the substrate 40 and a bottom gate dielectric layer 64 is disposed on the bottom gate layer 62. The material of the three layers is the same as the third embodiment. After cleaning and surface treatment of the bottom gate dielectric layer 64, the other layers including the ridges 66, the source layers 68, the drain layer 70, the semiconductor layers 72, the upper gate dielectric layer 74 and the upper gate layer 76 are formed on the bottom gate dielectric layer 64 to form a double gate TFT with an upper gate 76 and a bottom gate 62 according to the material and fabrication method of the first embodiment.

### SIXTH EMBODIMENT

The difference between the sixth and the fifth embodiments is that the materials of the semiconductor layers inkjet printed on the two ridges of the sixth embodiment are different. The sixth embodiment uses N type semiconductor inkjet printed on one ridge, and P type semiconductor inkjet printed on the other ridge to form a double gate CMOS TFT.

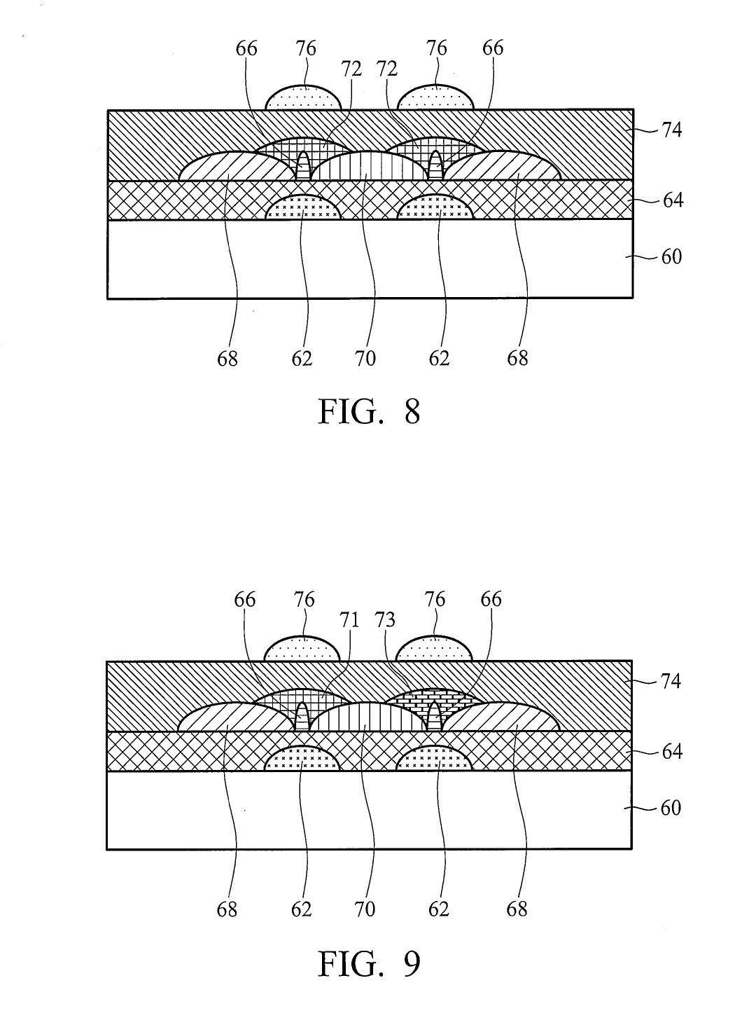

As shown in FIG. 9, a substrate 60 is first provided. A bottom gate layer 62 is then disposed on the substrate 40 and a bottom gate dielectric layer 64 is then disposed on the bottom gate layer 62. The materials of the layers 62 and 64 are the same as the fifth embodiment. After cleaning and surface treating the bottom gate dielectric layer 64, the other layers include the ridges 66, the source layers 68, the drain layer 70, the P type semiconductor layer 71, the N type semiconductor layer 73, the upper gate dielectric layer 74 and the upper gate layer 76 are formed on the bottom gate dielectric layer 64 to form a double gate CMOS TFT according to the material and fabrication method of the first and second embodiments.

In the first to sixth embodiments, a piezoelectric or a thermal bubble type nozzle performs the inkjet printing.

The invention provides the following advantages:

1. The width of the micro-line of the coffee ring formed by inkjet printing can be about 1˜50 μm, thus the channel length of the TFT shrinks and the operative current thereof is enhanced.

2. The channels of TFTs formed by inkjet printing can provide TFTs with a circular or linear shape.

3. The inkjet printing of the invention can be performed with organic materials which is extendable and flexible, thus the device can be formed on a flexible substrate to widen the application range.

4. TFTs formed by inkjet printing in combination with the coffee ring effect can fabricate two channels at one time to form a dual TFT device, or the two devices can be connected into one device to enhance the yield rate or increase the channel width thereof, such that the area of the device can be reduced and the open rate is increased.

5. N type and P type semiconductor materials inkjet printed on the two adjacent channels or the two adjacent positions of the same ridge formed by inkjet printing can form a TFT with COMS structure to widen the applications thereof.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A thin-film transistor, comprising:
a substrate;
a separating layer disposed over the substrate, wherein the separating layer includes a first ridge and a second ridge of a ring profile;
a source/drain layer disposed on opposite sides of the first ridge and opposite sides of the second ridge;
a first semiconductor layer disposed on the first ridge and portions of the source/drain layer adjacent to the first ridge;
a second semiconductor layer disposed on the second ridge and portions of the source/drain layer adjacent to the second ridge; and
a first gate dielectric layer and a first gate layer disposed over the substrate, thus completing a metal-oxide semiconductor (MOS) device.

2. The thin-film transistor as claimed in claim 1, wherein the ring profile is formed by inkjet printing in combination with a coffee ring effect.

3. The thin-film transistor as claimed in claim 1, wherein the first gate dielectric layer is disposed on the first semiconductor layer, the second semiconductor layer and the source/drain layer.

4. The thin-film transistor as claimed in claim 3, wherein the first gate layer is disposed on the first gate dielectric layer, corresponding to the first ridge and the second ridge.

5. The thin-film transistor as claimed in claim 1, wherein the first gate layer is disposed on the substrate, and underlying the separating layer and the source/drain layer.

6. The thin-film transistor as claimed in claim 5, wherein the first gate dielectric layer is disposed above the first gate layer, and underlying the separating layer and the source/drain layer.

7. The thin-film transistor as claimed in claim 1, wherein the separating layer is made of polymer.

8. The thin-film transistor as claimed in claim 7, wherein the polymer comprises poly(3-alkylthiophene) (P3AT), poly(9,9-dioctylfluorene-co-bithiophene) (F8T2), polymethyl methacrylate (PMMA), poly(4-vinylphenol) (PVP), polyvinyl alcohol (PVA), polyacrylonitrile (PAN), polyimide (PI), or polyoxymethylene (POM).

9. The thin-film transistor as claimed in claim 1, wherein the source/drain layer is a conductive layer formed from a solution of conductive material.

10. The thin-film transistor as claimed in claim 9, wherein the solution of conductive material comprises poly-3,4-ethylenedioxythiophene(PEDOT) or nanosilver paste.

11. The thin-film transistor as claimed in claim 1, wherein the first and second semiconductor layers, being the same or different, are N type or P type semiconductor.

12. The thin-film transistor as claimed in claim 11, wherein the semiconductor material comprises a derivative of carbon cluster, pentacene, poly(3-alkylthiophene) (P3AT), poly(9,9-dioctylfluorene-co-bithiophene) (F8T2), dicyano perylene-3,4,9,10-bis(dicarboximides) (PDI-CN₂), or ZnO.

13. The thin-film transistor as claimed in claim 12, wherein the derivative of carbon cluster is [6,6]-phenyl C61-butyric acid methyl ester (PCBM).

14. The thin-film transistor as claimed in claim 1, wherein the first gate dielectric layer is an organic insulating material.

15. The thin-film transistor as claimed in claim 14, wherein the organic insulating material comprises PMMA, PVP, PVA, PAN, PI or POM.

16. The thin-film transistor as claimed in claim 1, wherein the first gate dielectric layer is an inorganic insulating material.

17. The thin-film transistor as claimed in claim 16, wherein the inorganic insulating material comprises SiO₂, Ta₂O₅, Al₂O₃, or Si₃N₄.

18. The thin-film transistor as claimed in claim 4, wherein the first gate layer is a conductive layer formed from a metal or a solution of conductive material.

19. The thin-film transistor as claimed in claim 18, wherein the solution of conductive material comprises PEDOT or a nanometal solution.

20. The thin-film transistor as claimed in claim 19, wherein the nanometal solution is nanosilver paste.

21. The thin-film transistor as claimed in claim 18, wherein the metal material comprises Ag, Al, Au, alloys thereof, or combinations thereof.

22. The thin-film transistor as claimed in claim 5, wherein the first gate layer comprises a conductive layer formed from a metal, a solution of conductive material, or a heavily doped N type or P type semiconductor.

23. The thin-film transistor as claimed in claim 22, wherein the first gate layer comprises PEDOT, ITO, IZO, Ag, Au, Al, Cr or a heavily doped N type or P type Si, Ge, or GaAs.

24. The thin-film transistor as claimed in claim 1, wherein the first and the second semiconductor layers are both formed of the P type or N type semiconductor.

25. The thin-film transistor as claimed in claim 1, wherein the first and the second semiconductor layers are formed of P type and N type semiconductor respectively.

26. The thin-film transistor as claimed in claim 24, wherein the N type semiconductor comprises PCBM, PDI-CN₂ or ZnO.

27. The thin-film transistor as claimed in claim 25, wherein the N type semiconductor comprises PCBM, PDI-CN₂ or ZnO.

28. The thin-film transistor as claimed in claim 24, wherein the P type of semiconductor comprises pentacene, P3AT or a derivative of perfluorinated (PF) polymer.

29. The thin-film transistor as claimed in claim 25, wherein the P type of semiconductor comprises pentacene, P3AT or a derivative of PF polymer.

30. The thin-film transistor as claimed in claim 4, further comprising a second gate layer disposed on the substrate, and underlying the separating layer and the source/drain layer.

31. The thin-film transistor as claimed in claim 30, further comprising a second gate dielectric layer disposed above the second gate layer, and underlying the separating layer and the source/drain layer.

32. The thin-film transistor as claimed in claim 30, wherein the second gate layer comprises a conductive layer, a metal, or a heavily doped N type or P type semiconductor.

33. The thin-film transistor as claimed in claim 32, wherein the second gate layer comprises PEDOT, ITO, IZO, Ag, Au, Al or a heavily doped N type or P type Si, Ge, or GaAs.

34. The thin-film transistor as claimed in claim 31, wherein the second gate dielectric layer comprises an inorganic insulating material, an organic insulating material or combinations thereof.

35. The thin-film transistor as claimed in claim 34, wherein the inorganic insulating material comprises SiO₂, Ta₂O₅, Al₂O₃, or Si₃N₄.

36. A method of fabricating a thin-film transistor, comprising:
providing a substrate;
inkjet printing a separating layer over the substrate to form a coffee ring;
etching to remove a central part of the coffee ring, leaving a first ridge and a second ridge;
inkjet printing a source/drain layer on opposite sides of the first ridge and opposite sides of the second ridge;
inkjet printing or coating a first semiconductor layer on the first ridge and portions of the source/drain layer adjacent to the first ridge;
inkjet printing or coating a second semiconductor layer on the second ridge and portions of the source/drain layer adjacent to the second ridge; and
inkjet printing or coating a first gate dielectric layer and a first gate layer over the substrate to complete a metal-oxide semiconductor (MOS) device.

37. The method as claimed in claim 36, further comprising treating the first ridge and the second ridge with plasma to increase affinity of the first ridge and the second ridge to a semiconductor solution.

38. The method as claimed in claim 36, wherein the first gate dielectric layer is disposed on the first and the second semiconductor layers, and the source/drain layer.

39. The method as claimed in claim 38, wherein the first gate layer is disposed on the first gate dielectric layer, corresponding to the first and the second ridges.

40. The method as claimed in claim 36, wherein the first gate layer is disposed on the substrate, and underlying the separating layer and the source/drain layer.

41. The method as claimed in claim 40, wherein the first gate dielectric layer is disposed above the first gate layer, and underlying the separating layer and the source/drain layer.

42. The method as claimed in claim 36, wherein the separating layer is made of polymer.

43. The method as claimed in claim 36, wherein the etching is a surface micro-etching.

44. The method as claimed in claim 43, wherein the surface micro-etching is performed by plasma, dipping, spraying, dispensing or printing.

45. The method as claimed in claim 37, wherein the plasma comprises O₂, N₂, CF₄, SF₆ or combinations thereof.

46. The method as claimed in claim 36, wherein the source/drain layer is a conductive layer formed from a solution of conductive material.

47. The method as claimed in claim 36, wherein the first and the second semiconductor layers are made of a semiconductor material.

48. The method as claimed in claim 36, wherein the gate dielectric layer is made of an organic insulating material.

49. The method as claimed in claim 36, wherein the gate dielectric layer is made of an inorganic insulating material.

50. The method as claimed in claim 36, wherein the gate layer comprises a conductive layer formed from a metal or a solution of conductive material.

51. The method as claimed in claim 36, wherein the first and the second semiconductor layers are both formed of the P type or N type semiconductor.

52. The method as claimed in claim 36, wherein the first and second semiconductor layers are formed of P type and N type semiconductor respectively.

53. The method as claimed in claim 51, wherein the N type semiconductor material comprises a derivative of carbon cluster, PDI-CN₂ or ZnO.

54. The method as claimed in claim 52, wherein the N type semiconductor material comprises a derivative of carbon cluster, PDI-CN₂ or ZnO.

55. The method as claimed in claim 54, wherein the derivative of carbon cluster comprises PCBM.

56. The method as claimed in claim 51, wherein the P type semiconductor comprises pentacene, P3AT or a derivative of PF polymer.

57. The method as claimed in claim 52, wherein the P type semiconductor comprises pentacene, P3AT or a derivative of PF polymer.

58. The method as claimed in claim 36, wherein the inkjet printing is performed by a piezoelectric or thermal bubble type nozzle.

59. The method as claimed in claim 39, further comprising forming a second gate layer on the substrate, and underlying the separating layer and the source/drain layer.

60. The method as claimed in claim 59, further comprising forming a second gate dielectric layer above the second gate layer, and underlying the separating layer and the source/drain layer.

61. The method as claimed in claim 59, wherein the second gate layer comprises a conductive layer, a metal, or a heavily doped N type or P type semiconductor.

62. The method as claimed in claim 60, wherein the second gate dielectric layer comprises an inorganic insulating material, an organic insulating material or combinations thereof.
